(19) United States
(12) Patent Application Publication
(10) Pub. No.: US 2022/0158159 A1
(43) Pub. Date: May 19, 2022

(54) PROTECTION LAYER SOURCES

(71) Applicant: Applied Materials, Inc., Santa Clara, CA (US)

(72) Inventors: David Masayuki ISHIKAWA, Mountain View, CA (US); Ezhiylmurugan RANGASAMY, San Jose, CA (US); Kiran VACHHANI, Livermore, CA (US); Subramanya P. HERLE, Mountain View, CA (US); Girish Kumar GOPALAKRISHNAN NAIR, San Jose, CA (US)

(21) Appl. No.: 17/455,113

(22) Filed: Nov. 16, 2021

Related U.S. Application Data
(60) Provisional application No. 63/115,986, filed on Nov. 19, 2020.

(51) Int. Cl. H01M 4/04; H01M 4/1393; H01M 4/1395; H01M 4/62; H01M 4/36; C23C 14/58; C23C 14/34; C23C 14/56; C23C 16/54; C23C 16/56; H01M 4/38; H01M 4/587; C23C 14/08; C23C 14/06; C23C 14/14; C23C 14/12; C23C 14/10; C23C 14/30

(52) U.S. Cl. CPC H01M 4/0426; H01M 2004/027; H01M 4/1393; H01M 4/1395; H01M 4/628; H01M 4/366; C23C 14/5833; C23C 14/34; C23C 14/562; C23C 16/545; C23C 16/56; H01M 4/386; H01M 4/587; C23C 14/081; C23C 14/0647; C23C 14/0605; C23C 14/14; C23C 14/12; C23C 14/10; C23C 14/30; H01M 4/0428

(57) ABSTRACT

Methods, systems, and apparatuses for coating flexible substrates are provided. A coating system includes an unwinding module housing a feed reel capable of providing a continuous sheet of flexible material, a winding module housing a take-up reel capable of storing the continuous sheet of flexible material, and a processing module arranged downstream from the unwinding module. The processing module includes a plurality of sub-chambers arranged in sequence, each configured to perform one or more processing operations to the continuous sheet of flexible material. The processing module includes a coating drum capable of guiding the continuous sheet of flexible material past the plurality of sub-chambers along a travel direction. The sub-chambers are radially disposed about the coating drum and at least one of the sub-chambers includes a deposition module. The deposition module includes a pair of electron beam sources positioned side-by-side along a transverse direction perpendicular to the travel direction.

### CROSS-REFERENCE TO RELATED APPLICATIONS

This application claims benefit to U.S. Prov. Appl. No. 63/115,986, filed on Nov. 19, 2020, which is herein incorporated by reference.

### BACKGROUND

### Field

Implementations described herein generally relate to vacuum deposition systems and methods for processing a flexible substrate. More specifically, implementations of the present disclosure relate to roll-to-roll vacuum deposition systems and methods of forming at least two layers on a flexible substrate.

### Description of the Related Art

Rechargeable electrochemical storage systems are increasing in importance for many fields of everyday life. High-capacity energy storage devices, such as lithium-ion (Li-ion) batteries and capacitors, are used in a growing number of applications, including portable electronics, medical, transportation, grid-connected large energy storage, renewable energy storage, and uninterruptible power supply (UPS). In each of these applications, the charge/discharge time and capacity of energy storage devices are key parameters. In addition, the size, weight, and/or cost of such energy storage devices are also key parameters. Further, low internal resistance is integral for high performance. The lower the resistance, the less restriction the energy storage device encounters in delivering electrical energy. For example, in the case of a battery, internal resistance affects performance by reducing the total amount of useful energy stored by the battery as well as the ability of the battery to deliver high current.

Li-ion batteries are thought to have the best chance at achieving the sought after capacity and cycling. However, Li-ion batteries as currently constituted often lack the energy capacity and number of charge/discharge cycles for these growing applications.

Accordingly, there is a need in the art for faster charging, higher capacity energy storage devices that have improved cycling, and can be more cost effectively manufactured. There is also a need for components for an energy storage device that reduce the internal resistance of the storage device.

### SUMMARY

Implementations described herein generally relate to vacuum deposition systems and methods for processing a flexible substrate. More specifically, implementations of the present disclosure relate to roll-to-roll vacuum deposition systems and methods of forming at least two layers on a flexible substrate.

In one aspect, a flexible substrate coating system is provided. The coating system includes an unwinding module housing a feed reel capable of providing a continuous sheet of flexible material. The coating system further includes a winding module housing a take-up reel capable of storing the continuous sheet of flexible material. The coating system further includes a processing module arranged downstream from the unwinding module. The processing module includes a plurality of sub-chambers arranged in sequence, each configured to perform one or more processing operations to the continuous sheet of flexible material. The processing module further includes a coating drum capable of guiding the continuous sheet of flexible material past the plurality of sub-chambers along a travel direction, wherein the sub-chambers are radially disposed about the coating drum and at least one of the sub-chambers includes a deposition module. The deposition module includes a pair of electron beam sources positioned side-by-side along a transverse direction, wherein the transverse direction is perpendicular to the travel direction.

Implementations may include one or more of the following. The deposition module is defined by a sub-chamber body with an edge shield positioned over the sub-chamber body. The edge shield has one or more apertures defining a pattern of evaporated material that is deposited on the continuous sheet of flexible material. The edge shield has at least two apertures, with a first aperture defining a first strip of deposited material and a second aperture defining a second strip of deposited material. Each electron beam source includes at least one crucible capable of holding an evaporable material and an electron gun. The electron gun is operable for emitting an electron beam toward the evaporable material positioned in the crucible. Each electron beam source further includes e-gun steering capable of directing the electron beam of the electron gun from the evaporable material toward the continuous sheet of flexible material for electron irradiation of the deposited material on the continuous sheet of flexible material. The deposition module further includes an optical detector positioned to monitor a plume of evaporated material emitted from the electron beam source. The optical detector is configured to perform optical emission spectroscopy to measure the intensity of one or more wavelengths of light associated with the plume of evaporated material. The pair of electron beam sources are configured to deposit a lithium fluoride film on the continuous sheet of flexible material. The plurality of sub-chambers further includes a first sub-chamber comprising a sputtering source, wherein the first sub-chamber is positioned upstream from the sub-chamber comprising the deposition module. The sputtering source is configured to deposit at least one of aluminum, nickel, copper, alumina (Al₂O₃), boron nitride (BN), carbon, silicon oxide, or combinations thereof. The sub-chamber including the deposition module further includes a second sub-chamber comprising a thermal evaporation source. The thermal evaporation source is configured to deposit lithium metal. The plurality of sub-chambers further includes a third sub-chamber including a second deposition module similar to the deposition module and positioned downstream from the sub-chamber including the deposition module. The second deposition module is configured to deposit lithium fluoride. The third sub-chamber further includes a fourth sub-chamber comprising an organic thermal evaporation source. The coating system further includes a chemical vapor deposition (CVD) module positioned between the processing module and the winding module. The CVD module includes a multi-zone gas distribution assembly. The multi-zone gas distribution assembly is fluidly coupled with a first gas source. The first gas source is configured to supply at least one of titanium tetrachloride (TiCl₄), boron phosphate (BPO), and TiCl₄(HSR)₂, where R=C₆H₁₁ or C₅H₉, or combinations thereof. The multi-zone gas distribution assembly is fluidly coupled with a second gas source. The second gas source is configured to supply at least one of hydrogen sulfide (H₂S), carbon dioxide (CO₂), perfluorodecyltrichlorosilane (FDTS), and polyethylene glycol (PEG).

In another aspect, a method of forming a pre-lithiated anode structure is provided. The method includes depositing a first sacrificial anode layer on a prefabricated electrode structure. The prefabricated electrode structure includes a continuous sheet of flexible material coated with anode material. The method further includes depositing a second sacrificial anode layer on the first sacrificial anode layer. The method further includes depositing a third sacrificial anode layer on the second sacrificial anode layer. The method further includes densifying at least one of the first sacrificial anode layer, the second sacrificial anode layer, and the third sacrificial anode layer by exposing the sacrificial anode layers to electron beams from a pair of electron beam sources.

Implementations may include one or more of the following. The anode material is selected from graphite anode material, silicon anode material, or silicon-graphite anode material. The first sacrificial anode layer functions as a corrosion barrier, which minimizes electrochemical resistance between the anode material and/or the substrate and the second sacrificial anode layer. The first sacrificial anode layer includes a binary lithium compound, a ternary lithium compound, or a combination thereof. The first sacrificial anode layer is deposited using an electron beam evaporation source. The first sacrificial anode material layer 420 is a lithium fluoride layer. The second sacrificial anode material layer functions as a pre-lithiation layer, which provides lithium to pre-lithiate the prefabricated electrode structure. The second sacrificial anode layer is a lithium metal layer. The third sacrificial anode layer functions as an oxidation barrier, which minimizes electrochemical resistance between the lithium metal layer and subsequently deposited electrolyte. The third sacrificial anode layer includes a binary lithium compound, a ternary lithium compound, a sulfide compound, an oxide combination or a combination thereof. The third sacrificial anode layer is a lithium fluoride layer. A fourth sacrificial layer is deposited on the third sacrificial anode layer, wherein the fourth sacrificial layer functions as a wetting layer. The fourth sacrificial anode layer includes a polymer material selected from polymethylmethacrylate, polyethylene oxide, polyacrylonitrile, polyvinylidene fluoride, poly(vinylidene fluoride)-co-hexafluoropropylene, polypropylene, nylon, polyamides, polytetrafluoroethylene, polychlorotrifluoroethylene, polyterephthalate, silicone, silicone rubber, polyurethane, cellulose acetate, polystyrene, poly(dimethylsiloxane), or any combination thereof.

In yet another aspect, a method of forming an anode structure is provided. The method includes depositing a first persistent anode layer on a continuous sheet of flexible material. The method further includes depositing a second persistent anode layer on the first persistent lithium anode layer. The method further includes depositing a third persistent anode layer on the second persistent anode layer, wherein the third persistent anode layer is a lithium metal layer. The method further includes densifying at least one of the first persistent lithium anode layer, the second persistent anode layer, and the third persistent anode layer by exposing the persistent anode layers to electron beams from a pair of electron beam sources.

Implementations may include one or more of the following. The first persistent anode layer functions as a corrosion barrier, which minimizes electrochemical resistance between the continuous sheet of flexible material and the second persistent anode layer. The first persistent anode layer comprises a first persistent anode material layer comprising aluminum, nickel, copper, alumina (Al₂O₃), boron nitride (BN), carbon, silicon oxide, or a combination thereof. The first persistent anode layer is deposited using a sputtering source. The second persistent anode layer functions as a corrosion barrier, which minimizes electrochemical resistance between the continuous sheet of flexible material and the third persistent anode layer. The second persistent anode layer comprises a binary lithium compound, a ternary lithium compound, or a combination thereof. The second persistent anode layer is deposited using an electron beam evaporation source. The second persistent anode layer is a lithium fluoride layer.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of a vacuum processing system according to one or more implementations of the present disclosure.

FIG. 2 illustrates a schematic view of a deposition module including an electron beam deposition source according to one or more implementations of the present disclosure.

FIG. 3 illustrates a process flow chart summarizing one implementation of a method of forming an anode structure according to one or more implementations of the present disclosure.

FIG. 4 illustrates a schematic cross-sectional view of an anode electrode structure formed according to one or more implementations of the present disclosure.

FIG. 5 illustrates a process flow chart summarizing one implementation of a method of forming an anode structure according to one or more implementations of the present disclosure.

FIG. 6 illustrates a schematic cross-sectional view of yet another anode electrode structure formed according to one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

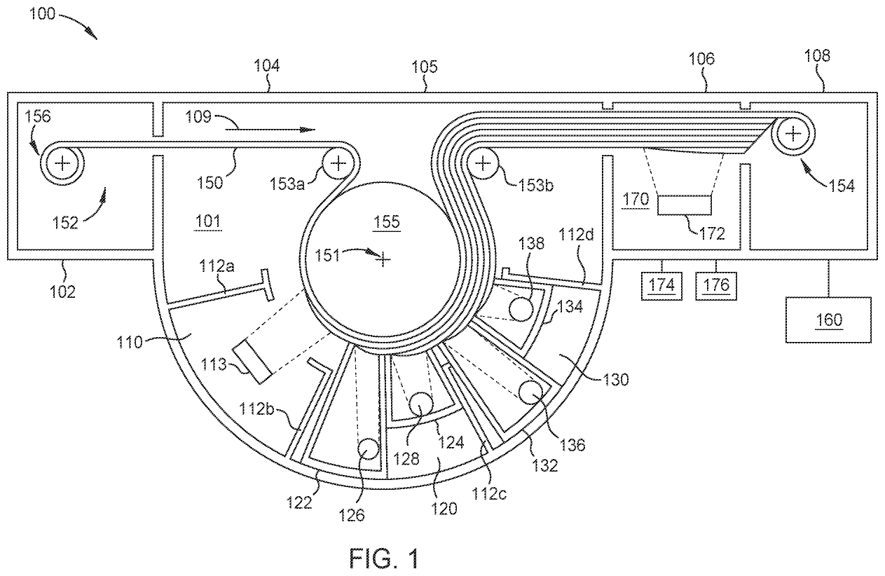

The following disclosure describes roll-to-roll vacuum deposition systems and methods of forming at least two layers on a flexible substrate. Certain details are set forth in the following description and in FIGS. 1-6 to provide a thorough understanding of various implementations of the disclosure. Other details describing well-known structures and systems often associated with web coating, electrochemical cells, and secondary batteries are not set forth in the following disclosure to avoid unnecessarily obscuring the description of the various implementations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations described herein will be described below in reference to a roll-to-roll coating system. The apparatus description described herein is illustrative and should not be construed or interpreted as limiting the scope of the implementations described herein. It should also be understood that although described as a roll-to-roll process, the implementations described herein can be performed on discrete substrates.

Energy storage devices, for example, batteries, typically consist of a positive electrode, an anode electrode separated by a porous separator, and an electrolyte, which is used as an ion-conductive matrix. Graphite anodes are the current state of the art but the industry is moving from the graphite based anode to silicon blended graphite anodes to increase cell energy density. However, silicon blended graphite anodes often suffer from irreversible capacity loss that occurs during the first cycle. Thus, there is a need for methods for replenishing this first cycle capacity loss.

Deposition of lithium metal is one such method for replenishing this first cycle capacity loss of graphite and silicon blended graphite anodes. While there are numerous methods for lithium metal deposition (e.g., thermal evaporation, lamination, printing, etc.), handling of lithium metal deposited on a spool before device stacking needs to be addressed, especially in a high-volume manufacturing environment. In order to address these handling issues, anode web coating often involves thin protection layer coatings. In the absence of a protection layer coating, the lithium metal surface is susceptible to adverse corrosion and oxidation. Lithium carbonate (Li₂CO₃) films are currently used as protection layer coating for lithium. However, lithium carbonate protection layers present several challenges. For example, carbonate coatings consume lithium which increases the amount of “dead lithium” and correspondingly decreases coulombic efficiency in the formed device. Current depositions processes for lithium carbonate can lead to the formation of lithium oxide, instead of lithium carbonate, which is an undesirable SEI component. In addition, carbonate coatings are difficult to activate given the slow adsorption rate of carbonate, which can cause significant variation in coating uniformity of the carbonate coating in both the machine and transverse directions. Furthermore, CO₂ adsorption lacks line-of-sight scalability and therefore is an unsuitable process for most high volume protection layer coatings including both sacrificial and protective applications.

Vacuum web coating for anode pre-lithiation and solid metal anode protection involves thick (three to twenty micron) metallic lithium deposition on double-side-coated and calendared alloy-type graphite anodes and current collectors, for example, six micron or thicker copper foil, nickel foil, or metallized plastic web. Pre-lithiation and solid metal anode web coating further involves thin, for example, less than 1-micron protection layer coatings. In the absence of protection layer coatings, the metallic lithium (via thermal evaporation or rolled foils) surface is susceptible to adverse corrosion and oxidation.

Impurities in the substrate can react with lithium and cause undesirable lithium corrosion. For example, alloy-type graphite anodes have trace levels (>10 ppm) of residual moisture (O₂ and H₂O) which can outgas during physical vapor deposition (PVD). This residual moisture trapped between the graphite anode and metallic lithium coating can increase the electrochemical resistance of the interface (via lithium oxide formation). Trapped residual moisture is slow to diffuse and therefore operationally cumbersome to vacuum degas. Not to be bound by theory, but it is believed that tuned deposition of a nanoscale (<100 nanometer thick) electrochemically active binary or ternary lithium compound as described herein to serve as a corrosion barrier between the alloy-type graphite anode and metallic lithium can improve anode quality without significant cost of ownership impact due to chemistry cost addition. For solid metal anodes, some copper foils have trace antioxidants and other residual byproducts from electrodeposition or rolling, which can react with lithium and cause undesirable lithium corrosion. Not to be bound by theory but it is believed that tuned deposition of a nanoscale (<100 nanometer thick) electrochemically active binary or ternary lithium compound as described herein can minimize lithium corrosion and can minimize lithium cracking along the copper grain boundaries. Further, it is believed that additive coating versus, for example, wet cleaning, is the preferred approach for high volume scaling.

Oxygen, nitrogen, and hydrogen (O—N—H) can react with lithium during web unloading and cell assembly in a dry room environment to form an electrochemically insulating layer of lithium oxide on freshly deposited metallic lithium. Not to be bound by theory but it is believed that the aforementioned binary and ternary lithium compounds used as corrosion barriers between the substrate and lithium can also serve as oxidation barriers between the lithium and environment to minimize air reactivity. In addition to lithium compounds, the present disclosure has devised CVD hardware and methods for applying titanium disulfide and other reactive films via single and dual precursor chemical pathways. The aforementioned CVD hardware can also deposit conventional dry carbon dioxide.

In some aspects, methods and systems for forming lithium anode devices are provided. In some implementations, a pre-metalation film stack including metallic lithium metal sandwiched between corrosion and oxidation barriers is produced using the CVD and PVD modules described herein. The film stack can be adapted for among other things, continuous lithium-ion battery (“LIB”) electric vehicle (“EV”) anode pre-lithiation, consumer electric (“CE”) solid metal anode protection, or to manufacture consumable thin lithium tape.

In some implementations, a pre-lithiation film stack and methods for making the pre-lithiation film stack are provided. The pre-lithiation film stack includes a graphite-containing anode film/an optional binary or ternary lithium corrosion barrier film)/a lithium film formed via evaporation/and a binary or ternary lithium oxidation barrier or sulfide or oxide barrier film.

In another implementation, a metal anode film stack and methods for making the metal anode film stack are provided. The metal anode film stack includes a metal current collector/a binary or ternary lithium corrosion barrier/a lithium metal anode film via evaporation/and a binary or ternary lithium oxidation barrier film.

In yet another implementation, a lithium transfer foil and methods for making the lithium transfer foil are provided. The lithium transfer foil includes a carrier substrate/a binary or ternary lithium oxidation barrier/less than 20 microns of a lithium film formed via evaporation/and a binary or ternary lithium oxidation barrier.

In some aspects, the PVD and CVD modules described herein can be integrated in conventional vacuum web coaters, which typically are unsuitable for toxic and pyrophoric precursors, for example, lithium fluoride (solid), hydrogen disulfide (gas), and other lithium-ion battery chemistry. In some implementations, the PVD modules described herein employ a transverse array of e-beam guns for crucible evaporation and for post-treatment electron web irradiation to increase coating density or modulate coating composition. The PVD modules described herein are further capable of lithium and lithium compound deposition singularly or in co-deposition mode. The CVD modules described herein enable dual and single source precursors for conventional dry carbon dioxide gas treatment or low temperature (<200° C.) organothiol-based titanium disulfide deposition.

In some aspects, the PVD and CVD modules described herein enable pre-metalation and corresponding protection layer deposition in order to deposit cell and battery application-specific metallic lithium reservoirs that are either: (1) sacrificial, in that the anode coatings are fully consumed after first cycle charging; or (2) persistent, in that the anode coatings remain after first cycle charging. The capability to controllably and precisely deliver stable electrochemically active lithium to the cell during electrolyte filling and SEI formation and further, to prevent adverse metallic lithium conversion to lithium oxide or other adverse compounds facilitates high quality and high yield anode pre-lithiation and anode protection layer deposition. Alloy-type anode pre-lithiation control improves lithium-ion battery coulombic efficiency. Anode coating with pinhole free and electrochemically active protection layers resist dendrite formation.

In some aspects, CVD is used for sacrificial protection layers and PVD is used for persistent protection layers. In some implementations, the PVD module described herein, which accommodates two materials in one standard web compartment enables reactive alloying via co-deposition. The flexibility provided by the combination of non-standard chemistries and unconventional CVD and PVD sources can enable conventional web coaters to be effectively retooled in order to service captive anode manufacturing and tool coating business models.

In some aspects, a hybrid PVD source is provided. The hybrid PVD source includes a resistively heated crucible and an electron beam heated crucible in a shared compartment. Positioning the two PVD sources in the shared compartment minimizes the latency between lithium film deposition and the overlying protection layer. Both the lithium film and the overlying protection layer can be deposited singularly in two passes or co-deposited in a single pass in one compartment.

Using the implementations described herein, the deposited lithium metal, either single-sided or dual-sided, can be protected during winding and unwinding of the reels downstream. Deposition of the protective films described herein has several potential advantages. First, reels of electrodes containing lithium metal can be wound and unwound without lithium metal touching adjacent electrodes. Second, a stable solid electrolyte interface (SEI) can be established for better cell performance and high electrochemical utilization of lithium metal. The protective layer can also help to suppress or eliminate lithium dendrite, especially at high current density operation. In addition, the use of protective films reduces the complexity of manufacturing systems and is compatible with current manufacturing systems.

As described herein, binary lithium compounds include, but are not limited to, lithium bismuth (Li₃Bi), lithium carbonate (Li₂CO₃), lithium fluoride (LiF), lithium indium (Li₁₃In₃), lithium nitride (Li₃N), lithium oxide (Li₂O), lithium sulfide (Li₂S), lithium tin (Li_{4.4}Sn), lithium phosphide (Li₃P), lithium tin phosphorous sulfide (Li₁₀SnP₂S₁₂), or a combination thereof.

As described herein, ternary lithium compounds include, but are not limited to, lithium phosphate (Li₃PO₄), lithium thiophosphate (LPS; β-Li₃PS₄), lithium titanate spinel oxide (LTO; Li₄Ti₅O₁₂), ternary lithium oxides, ternary lithium nitrides, or a combination thereof.

As used herein, a sacrificial film is designed to be consumed or destroyed in fulfilling a protection purpose or function before first charge of a completed cell incorporating the anode structure.

As used herein, a persistent film is designed to provide one or more functions after first charge of a completed cell incorporating the anode structure.

It is noted that while the particular substrate on which some implementations described herein can be practiced is not limited, it is particularly beneficial to practice the implementations on flexible substrates, including for example, web-based substrates, panels and discrete sheets. The substrate can also be in the form of a foil, a film, or a thin plate.

It is also noted here that a flexible substrate or web as used within the implementations described herein can typically be characterized in that it is bendable. The term “web” can be synonymously used to the term “strip” or the term “flexible substrate.” For example, the web as described in implementations herein can be a foil.

It is further noted that in some implementations where the substrate is a vertically oriented substrate, the vertically oriented substrate can be angled relative to a vertical plane. For example, in some implementations, the substrate can be angled from between about 1 degree to about 20 degrees from the vertical plane. In some implementations where the substrate is a horizontally oriented substrate, the horizontally oriented substrate can be angled relative to a horizontal plane. For example, in some implementations, the substrate can be angled from between about 1 degree to about 20 degrees from the horizontal plane. As used herein, the term “vertical” is defined as a major surface or deposition surface of the flexible conductive substrate being perpendicular relative to the horizon. As used herein, the term “horizontal” is defined as a major surface or deposition surface of the flexible conductive substrate being parallel relative to the horizon.

It is further noted that in the present disclosure, a “roll” or a “roller” can be understood as a device, which provides a surface, with which a substrate (or a part of a substrate) can be in contact during the presence of the substrate in the processing system. At least a part of the “roll” or “roller” as referred to herein can include a circular-like shape for contacting the substrate to be processed or already processed. In some implementations, the “roll” or “roller” can have a cylindrical or substantially cylindrical shape. The substantially cylindrical shape can be formed about a straight longitudinal axis or can be formed about a bent longitudinal axis. According to some implementations, the “roll” or “roller” as described herein can be adapted for being in contact with a flexible substrate. For example, a “roll” or “roller” as referred to herein can be a guiding roller adapted to guide a substrate while the substrate is processed (such as during a deposition process) or while the substrate is present in a processing system; a spreader roller adapted for providing a defined tension for the substrate to be coated; a deflecting roller for deflecting the substrate according to a defined travelling path; a processing roller for supporting the substrate during processing, such as a process drum, e.g. a coating roller or a coating drum; an adjusting roller, a supply roll, a take-up roll or the like. The “roll” or “roller” as described herein can comprise a metal. In some implementations, the surface of the roller device, which is to be in contact with the substrate can be adapted for the respective substrate to be coated. Further, it is to be understood that according to some implementations, the rollers as described herein can be mounted to low friction roller bearings, particularly with a dual bearing roller architecture. Accordingly, roller parallelism of the transportation arrangement as described herein can be achieved and a transverse substrate “wandering” during substrate transport can be eliminated.

FIG. 1 illustrates a schematic side view of a flexible substrate coating system 100 according to one or more implementations of the present disclosure. The flexible substrate coating system 100 can be a SMARTWEB® system, manufactured by Applied Materials, adapted for manufacturing lithium-containing anode film stacks according to the implementations described herein. The flexible substrate coating system 100 can be used for manufacturing lithium-containing anodes, and particularly for film stacks for lithium-containing anodes. The flexible substrate coating system 100 includes a common processing environment 101 in which some or all of the processing actions for manufacturing lithium-containing anodes can be performed. In one or more examples, the common processing environment 101 is operable as a vacuum environment. In other examples, the common processing environment 101 is operable as an inert gas environment.

The flexible substrate coating system 100 is constituted as a roll-to-roll system including an unwinding module 102, a processing module 104, an optional chemical vapor deposition (CVD) module 106, and a winding module 108. The processing module 104 includes a chamber body 105 that defines the common processing environment 101.

In some implementations, the processing module 104 comprises a plurality of processing modules or sub-chambers 110, 120, and 130 arranged in sequence, each configured to perform one processing operation to a continuous sheet of flexible material 150 or web of material. In one or more examples, as depicted in FIG. 1, the sub-chambers 110-130 are radially disposed about a coating drum 155. The sub-chambers 110-130 are separated by partition walls 112a-112d (collectively 112). For example, the first sub-chamber 110 is defined by partition walls 112a and 112b, the second sub-chamber 120 is defined by partition walls 112b and 112c, and the third sub-chamber 130 is defined by partition walls 112c and 112d. In one or more examples, the sub-chambers 110-130 are closed with the exception of narrow, arcuate gaps, by partition walls 112. Although the first sub-chamber 110 is depicted as having a single deposition source 113, each sub-chamber 110-130 can be divided into two or more compartments each including a separate deposition source.

In one implementation as shown in FIG. 1, the second sub-chamber 120 is divided into a first compartment 122 and a second compartment 124 each containing a deposition source 126 and 128 respectively and the third sub-chamber 130 is divided into a third compartment 132 and a fourth compartment 134 each containing a deposition source 136 and 138 respectively. The compartments can be closed or isolated relative to adjacent compartments except for a narrow opening allowing for deposition over the coating drum 155. At least one of the deposition sources 113, 126, 128, 136 and 138 includes an electron beam gun. In addition, arrangements other than radial are contemplated. For example, in another implementation, the sub-chambers 110-130 can be positioned in a linear configuration.

In some implementations, the sub-chambers 110-130 are stand-alone modular sub-chambers wherein each modular processing chamber is structurally separated from the other modular sub-chambers. Therefore, each of the stand-alone modular sub-chambers, can be arranged, rearranged, replaced, or maintained independently without affecting each other. Although three sub-chambers 110-130 are shown, it should be understood that any number of sub-chambers may be included in the flexible substrate coating system 100.

The sub-chambers 110-130 can include any suitable structure, configuration, arrangement, and/or components that enable the flexible substrate coating system 100 to deposit a lithium-containing anode film stack according to implementations of the present disclosure. For example, but not limited to, the sub-chambers may include suitable deposition systems including coating sources, power sources, individual pressure controls, deposition control systems, and temperature control. In some implementations, the sub-chambers are provided with individual gas supplies. As described herein, the sub-chambers 110-130 are typically separated from each other for providing good gas separation. The flexible substrate coating system 100 described herein is not limited in the number of sub-chambers. For example, the flexible substrate coating system 100 may include, but is not limited to, 3, 6, or 12 sub-chambers.

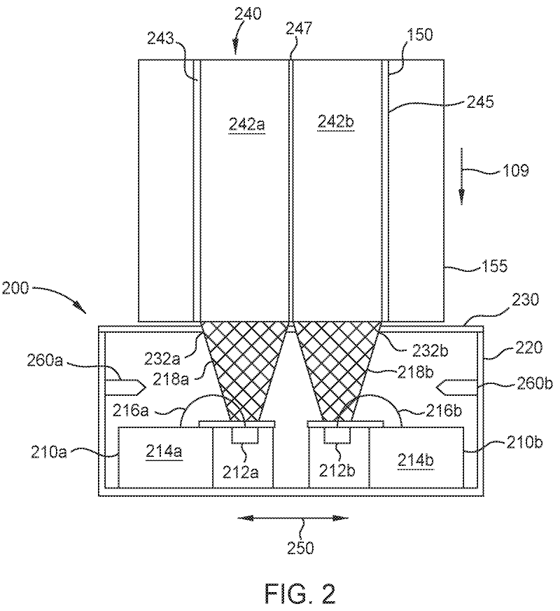

The sub-chambers 110-130 typically include one or more deposition sources 113, 126, 128, 136 and 138. Generally, the one or more deposition sources as described herein include an electron beam source and additional sources, which can be selected from the group of CVD sources, PECVD sources, and various PVD sources. The electron beam source will be described in detail in FIG. 2. The one or more deposition sources 113, 126, 128, 136, and 138 can include one or more evaporation sources. Examples of evaporation sources include thermal evaporation sources and electron beam evaporation sources. In one or more examples, the evaporation source is a thermal evaporation source and/or an electron beam evaporation source. In some implementations, the evaporation source is a lithium (Li) source. Further, the evaporation source can also be an alloy of two or more metals. The material to be deposited (e.g., lithium) can be provided in a crucible. The lithium can, for example, be evaporated by thermal evaporation techniques or by electron beam evaporation techniques.

The one or more deposition sources 113, 126, 128, 136, and 138 can further include one or more sputtering sources. Examples of sputtering sources include magnetron sputter sources, DC sputter sources, AC sputter sources, pulsed sputter sources, radio frequency (RF) sputtering sources, or middle frequency (MF) sputtering sources. For instance, MF sputtering with frequencies in the range of 5 kHz to 100 kHz, for example, 30 kHz to 50 kHz, can be provided. As used herein, “magnetron sputtering” refers to sputtering performed using a magnet assembly, that is, a unit capable of a generating a magnetic field. Typically, such a magnet assembly includes a permanent magnet. This permanent magnet is typically arranged within a rotatable target or coupled to a planar target in a manner such that the free electrons are trapped within the generated magnetic field generated below the rotatable target surface. Such a magnet assembly may also be arranged coupled to a planar cathode.

In one or more examples, deposition source 113 is a sputtering source, deposition source 126 is an electron beam evaporation source, deposition source 128 is a thermal evaporation source, deposition source 136 is an electron beam evaporation source, and the deposition source 138 is an organic thermal evaporation source.

In some implementations, the CVD module 106 is positioned between the processing module 104 and the winding module 108, for example, upstream from the winding module 108 and downstream from the processing module 104. In some implementations, the CVD module 106 includes a processing region 170. The processing region 170 includes one or more deposition sources 172 for introducing process gases into the CVD module 106. In some implementations where double-sided coating is performed, the CVD module 106 includes an additional deposition source positioned to deposit material on the opposite side of the continuous sheet of flexible material 150. In one or more examples, the deposition source 172 is a multi-zone gas distribution assembly or showerhead. The processing region 170 can include one or more electrodes for forming an in-situ plasma within the CVD module 106. The processing region 170 can be coupled with a remote plasma source for supplying a remote plasma to the processing region 170.

In some implementations, the sub-chambers 110-130 are configured to process both sides of the continuous sheet of flexible material 150. Although the flexible substrate coating system 100 is configured to process the continuous sheet of flexible material 150, which is horizontally oriented, the flexible substrate coating system 100 may be configured to process substrates positioned in different orientations, for example, the continuous sheet of flexible material 150 may be vertically oriented. In some implementations, the continuous sheet of flexible material 150 is a flexible conductive substrate. In some implementations, the continuous sheet of flexible material 150 includes a conductive substrate with one or more layers formed thereon. In some implementations, the conductive substrate is a copper substrate.

In some implementations, the flexible substrate coating system 100 comprises a substrate transport arrangement 152. The substrate transport arrangement 152 can include any transfer mechanism capable of moving the continuous sheet of flexible material 150 through the processing region of the sub-chambers 110-130. The substrate transport arrangement 152 can include a reel-to-reel system with a common take-up-reel 154 positioned in the winding module 108, the coating drum 155 positioned in the processing module 104, and a feed reel 156 positioned in the unwinding module 102. The take-up reel 154, the coating drum 155, and the feed reel 156 may be individually heated. The take-up reel 154, the coating drum 155 and the feed reel 156 can be individually heated using an internal heat source positioned within each reel or an external heat source. The substrate transport arrangement 152 can further include one or more auxiliary transfer reels 153a, 153b positioned between the take-up reel 154, the coating drum 155, and the feed reel 156. According to one aspect, at least one of the one or more auxiliary transfer reels 153a, 153b, the take-up reel 154, the coating drum 155, and the feed reel 156 can be driven and rotary, by a motor.

The flexible substrate coating system 100 includes the feed reel 156 and the take-up reel 154 for moving the continuous sheet of flexible material 150 past the different sub-chambers 110-130. In some implementations, the deposition source 113 of the first sub-chamber 110 includes a sputtering source configured to deposit a first layer on the continuous metal sheet of flexible material 150. In one or more examples, the deposition source 113 is a sputtering source configured to deposit at least one of aluminum, nickel, copper, alumina (Al₂O₃), boron nitride (BN), carbon, silicon oxide, or combinations thereof. Not to be bound by theory, but it is believed that the first layer minimizes corrosion and reduces bagginess of the underlying continuous metal sheet of flexible material 150.

The second sub-chamber 120 can be configured to deposit any of the binary films, ternary films, or polymer films described herein. In some implementations, the deposition source 126 positioned in the first compartment 122 of the second sub-chamber 120 is an evaporation source configured to deposit a second layer over the first layer. In one or more examples, the deposition source 126 is an electron beam evaporation source, for example the electron beam evaporation source 210, configured to deposit a first lithium fluoride layer. In other examples, the deposition source 126 is an organic thermal evaporation source configured to deposit any of the polymer materials described herein. The second compartment 124 of the second sub-chamber 120 includes a deposition source 128 configured to deposit a third layer over the second layer. In one or more examples, the deposition source 128 is a thermal evaporation source configured to deposit a lithium metal layer. In other examples, the deposition source 128 is an organic thermal evaporation source configured to deposit any of the polymer materials described herein.

The third sub-chamber 130 can be configured to deposit any of the binary films, ternary films, or polymer films described herein. In some implementations, the third compartment 132 of the third sub-chamber 130 includes the deposition source 136, which is a third evaporation source configured to deposit a fourth layer over the third layer. In one or more examples, the deposition source 136 is an electron beam evaporation source, for example, the electron beam evaporation source 210, configured to deposit a second lithium fluoride layer. In other examples, the deposition source 136 is an organic thermal evaporation source configured to deposit any of the polymer materials described herein. The fourth compartment 134 of the third sub-chamber 130 includes the deposition source 138, which can be a fourth evaporation source configured to deposit a fifth layer over the fourth layer. In one or more examples, the deposition source 138 is an electron beam evaporation source configured to deposit a second lithium fluoride layer. In other examples, the deposition source 138 is an organic thermal evaporation source configured to deposit any of the polymer materials described herein.

The CVD module 106 can be configured to deposit any of the binary films, ternary films, or polymer films described herein. In addition, the CVD module can be configured to deposit a metal sulfide, for example, titanium disulfide (TiS₂). In some implementations, the CVD module 106 includes a first gas source 174 configured to supply at least one of titanium tetrachloride (TiCl₄), boron phosphate (BPO), and TiCl₄(HSR)₂, where R=C₆H₁₁ or C₅H₉, or combinations thereof. The CVD module 106 can further include a second gas source 176 configured to supply at least one of hydrogen sulfide (H₂S), carbon dioxide (CO₂), perfluorodecyltrichlorosilane (FDTS), and polyethylene glycol (PEG). Titanium disulfide films are conductive and typically have a high lithium diffusion coefficient at ambient temperature and exhibit reversible lithium intercalation even after numerous discharge cycles. In some implementations, the titanium disulfide film is prepared via a CVD process using titanium tetrachloride and organothiols. In one or more examples, titanium disulfide is prepared by treatment of titanium tetrachloride with alkane-thiols in hexane at ambient temperature. In other examples, titanium disulfide films are fabricated at low pressure (0.1 mmHg) in a heated reaction zone within a temperature range of 200 degrees Celsius to 600 degrees Celsius.

In operation, the continuous sheet of flexible material 150 is unwound from the feed reel 156 as indicated by the substrate travel direction shown by arrow 109. The continuous sheet of flexible material 150 can be guided via the one or more auxiliary transfer reels 153a, 153b. It is also possible that the continuous sheet of flexible material 150 is guided by one or more substrate guide control units (not shown) that shall control the proper run of the continuous sheet of flexible material 150, for instance, by fine adjusting the orientation of the continuous sheet of flexible material 150.

After uncoiling from the feed reel 156 and running over the auxiliary transfer reel 153a, the continuous sheet of flexible material 150 is then moved through the deposition areas provided at the coating drum 155 and corresponding to positions of the one or more deposition sources 113, 126, 128, 136, 138, and 172. During operation, the coating drum 155 rotates around axis 151 such that the flexible substrate moves in a travel direction represented by arrow 109.

The flexible substrate coating system 100 further includes a system controller 160 operable to control various aspects of the flexible substrate coating system 100. The system controller 160 facilitates the control and automation of the flexible substrate coating system 100 and can include a central processing unit (CPU), memory, and support circuits (or I/O). Software instructions and data can be coded and stored within the memory for instructing the CPU. The system controller 160 can communicate with one or more of the components of the flexible substrate coating system 100 via, for example, a system bus. A program (or computer instructions) readable by the system controller 160 determines which tasks are performable on a substrate. In some aspects, the program is software readable by the system controller 160, which can include code to control removal and replacement of the multi-segment ring. Although shown as a single system controller 160, it should be appreciated that multiple system controllers can be used with the aspects described herein.

FIG. 2 illustrates a schematic view of a deposition module 200 including a pair of electron beam evaporation sources 210a, 210b (collectively 210) according to one or more implementations of the present disclosure. The deposition module 200 can be used in the flexible substrate coating system 100. In some implementations, the deposition module 200 replaces one of the compartments 122, 124, 132 and 134 positioned in the flexible substrate coating system 100. In one or more examples, the deposition module 200 replaces the first compartment 122 and the third compartment 132. The deposition module 200 is depicted as being adjacent to the coating drum 155 of the flexible substrate coating system 100 having the continuous sheet of flexible material 150 disposed thereon. Although depicted as part of the flexible substrate coating system 100, the deposition module can be used with other coating systems.

The deposition module 200 is defined by a sub-chamber body 220 with an edge shield 230 or mask positioned over the sub-chamber body 220. The edge shield 230 includes one or more apertures 232a, 232b (collectively 232), which define a pattern of evaporated material that is deposited on the continuous sheet of flexible material 150. In one or more examples, the edge shield 230 includes two apertures. As depicted in FIG. 2, the edge shield 230 defines a pattern of deposited material 240 on the continuous sheet of flexible material 150. The patterned film of deposited material 240 includes a first strip of deposited material 242a and a second strip of deposited material 242b both extending in the substrate travel direction shown by arrow 109 of the continuous sheet of flexible material 150. The edge shield 230 leaves an uncoated strip along a near edge 243 of the continuous sheet of flexible material 150, an uncoated strip along a far edge 245 of the continuous sheet of flexible material 150, and an uncoated strip 247 defined between the first strip of deposited material 242a and the second strip of deposited material 242b. In one or more examples, the edge shield 230 includes the two apertures 232a, 232b, with the first aperture 232a defining the first strip of deposited material 242a and the second aperture 232b defining the second strip of deposited material 242b.

Each electron beam evaporation source 210a, 210b (collectively 210) includes at least one crucible 212a, 212b (collectively 212) and an electron gun 214a, 214b (collectively 214). The crucible 212 holds an evaporable material. The electron gun 214 is operable for emitting an electron beam toward the evaporable material positioned in crucible 212. In operation, an electron beam 216a, 216b (collectively 216) from the electron gun 214 is directed at the evaporable material. The material is heated and evaporated. A plume of evaporated material 218a, 218b (collectively 218) is drawn to the continuous sheet of flexible material 150 where the patterned film of deposited material 240 is formed on the continuous sheet of flexible material 150.

The electron gun 214a, 214b is also operable for emitting an electron beam toward the deposited films on the continuous sheet of flexible material 150. For example, e-gun steering can direct the electron beam of the electron gun 214a, 214b from the evaporable material toward the continuous sheet of flexible material 150 for electron irradiation of the deposited material on the continuous sheet of flexible material 150. This electron irradiation can densify the deposited films via direct heating.

The electron gun 214a, 214b can turn on/off instantly with no latency, which provides greater control over film deposition and patterning. The electron gun 214a, 214b can deposit materials, which are typically of higher quality than their resistively heated counterparts. In addition, the electron gun 214a, 214b can evaporate solids, liquids, and/or powders, which enables the deposition of a variety of films.

The electron beam evaporation sources 210a, 210b are positioned side-by-side along the transverse direction represented by arrow 250, which is perpendicular to the travel direction represented by arrow 109. Positioning the electron beam evaporation sources 210a, 210b along the transverse direction allows for the strip coating pattern depicted in FIG. 2.

In some implementations, the deposition module 200 further includes an optical detector 260a, 260b (collectively 260). The optical detector 260 can be attached to a wall of the sub-chamber body 220. The optical detector 260 can be positioned to monitor the plume of evaporated material 218a, 218b to help tune the quality of the deposited films. In one or more examples, the optical detector 260 uses optical emission spectroscopy (OES) to measure the intensity of one or more wavelengths of light associated with the plume of evaporated material 218. The OES can communicate with the system 240212 controller 160 or a separate controller.

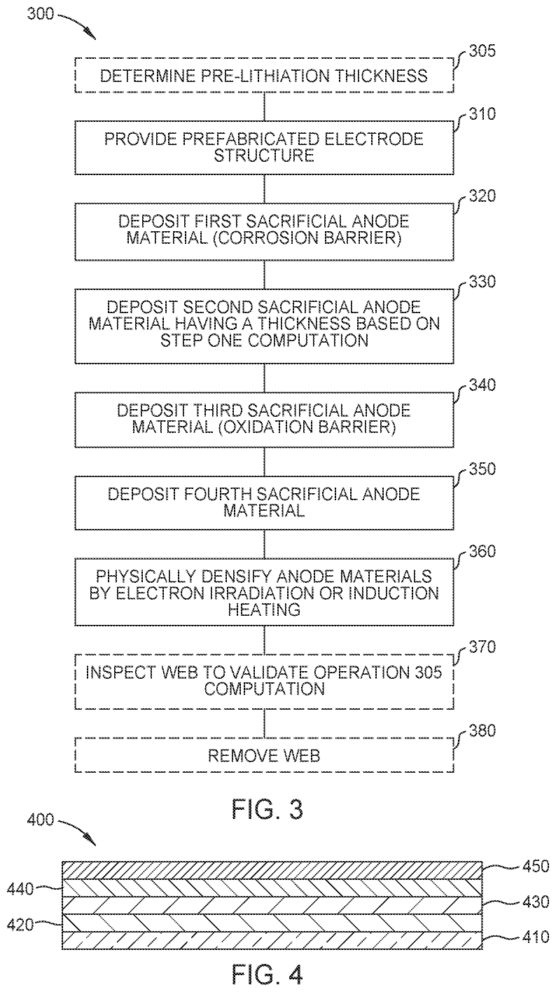

FIG. 3 illustrates a process flow chart summarizing one implementation of a processing sequence 300 of forming a pre-lithiated anode structure according to one or more implementations of the present disclosure. FIG. 4 illustrates a schematic cross-sectional view of a pre-lithiated anode structure 400 formed according to the processing sequence 300 of FIG. 3. The processing sequence 300 can be used to pre-lithiate a single-sided electrode structure or a dual-sided electrode structure. The processing sequence 300 can be performed using, for example, a coating system, such as the flexible substrate coating system 100 depicted in FIG. 1 including the deposition module 200 of FIG. 2.

Optionally, at operation 305, the thickness of the pre-lithiation layer to be deposited is determined. The thickness of the pre-lithiation layer can be based on factors such as lithium loss during cell assembly, for example Li₂O formation; ageing, for example, silicon oxide formation; and cycling, for example, SEI formation.

At operation 310, a prefabricated electrode structure 410, which includes a substrate coated with anode material, is provided. The continuous sheet of flexible material 150 can comprise the prefabricated electrode structure 410. The substrate can be a current collector as described herein. Examples of metals that the current collectors can be comprised of include aluminum (Al), copper (Cu), zinc (Zn), nickel (Ni), cobalt (Co), tin (Sn), silicon (Si), manganese (Mn), magnesium (Mg), alloys thereof, or combinations thereof. The web or continuous sheet of flexible material 150 can include a polymer material on which a current collector is subsequently formed. The polymer material can be a resin film selected from a polypropylene film, a polyethylene terephthalate (PET) film, a polyphenylene sulfide (PPS) film, and a polyimide (PI) film. The substrate can be a flexible substrate or web, such as the continuous sheet of flexible material 150, which can be used in a roll-to-roll coating system. In one aspect, the substrate is a negative current collector, such as a copper current collector. In one aspect, the prefabricated electrode structure 410 is a single-sided anode structure including a substrate coated with anode material. In one or more examples, the prefabricated electrode structure 410 includes a copper current collector coated with a graphite anode material, a silicon anode material, or a silicon-graphite anode material formed thereon. In another aspect, the prefabricated electrode structure 410 is a dual-sided anode structure. In one or more examples, the dual-sided anode structure includes a copper current collector coated on opposing sides with graphite anode material, silicon anode material, or silicon-graphite anode material.

At operation 320, a first sacrificial anode material, for example, first sacrificial anode material layer 420 is deposited on the prefabricated electrode structure 410. The first sacrificial anode material layer 420 functions as a corrosion barrier, which minimizes electrochemical resistance between the anode and/or current collector and the subsequently deposited lithium metal film. The first sacrificial anode material layer 420 comprises, consists essentially of, or consists of a binary lithium compound, a ternary lithium compound, or a combination thereof. The first sacrificial anode material layer 420 can be deposited using an electron beam evaporation source, for example, the electron beam evaporation source 210. In one or more examples, the first sacrificial anode material layer 420 is formed in the first compartment 122 of the second sub-chamber 120 using the first evaporation source, for example, the electron beam evaporation source 210, configured to deposit the first sacrificial anode material layer 420. In one or more examples, the first sacrificial anode material layer 420 is a lithium fluoride layer.

At operation 330, a second sacrificial anode material, for example, second sacrificial anode material layer 430 is deposited on the first sacrificial anode material layer 420. The second sacrificial anode material layer 430 functions as a pre-lithiation layer, which provides lithium to pre-lithiate the prefabricated electrode structure 410. The second sacrificial anode material layer 430 comprises, consists essentially of, or consists of lithium metal. The second sacrificial anode material layer 430 can be deposited using a thermal evaporation source. In one or more examples, the second sacrificial anode material layer 430 is formed in the second compartment 124 of the second sub-chamber 120 using the deposition source 128, which is a thermal evaporation source configured to deposit the second sacrificial anode material layer 430. In one or more examples, the second sacrificial anode material layer 430 is a lithium metal layer.

At operation 340, a third sacrificial anode material, for example, third sacrificial anode material layer 440 is deposited on the second sacrificial anode material layer 430. The third sacrificial anode material layer 440 functions as an oxidation barrier, which minimizes electrochemical resistance between the lithium metal layer and electrolyte in the formed cell. The third sacrificial anode material layer 440 comprises, consists essentially of, or consists of a binary lithium compound, a ternary lithium compound, a sulfide compound, an oxide combination or a combination thereof. The third sacrificial anode material layer 440 can be deposited using an electron beam evaporation source, for example, the electron beam evaporation source 210. In one or more examples, the third sacrificial anode material layer 440 is formed in the third compartment 132 of the third sub-chamber 130 using the deposition source 136, which can be an electron beam evaporation source configured to deposit the third sacrificial anode material layer 440. In one or more examples, the third sacrificial anode material layer 440 is a lithium fluoride layer.

At operation 350, a fourth sacrificial anode material, for example, fourth sacrificial anode material layer 450 is deposited on the third sacrificial anode material layer 440. The fourth sacrificial anode material layer 450 functions as a wetting layer, which enhances electrolyte wetting. The fourth sacrificial anode material layer 450 comprises, consists essentially of, or consists of a polymer material. Exemplary polymer materials include but are not limited to polymethylmethacrylate, polyethylene oxide, polyacrylonitrile, polyvinylidene fluoride, poly(vinylidene fluoride)-co-hexafluoropropylene, polypropylene, nylon, polyamides, polytetrafluoroethylene, polychlorotrifluoroethylene, polyterephthalate, silicone, silicone rubber, polyurethane, cellulose acetate, polystyrene, poly(dimethylsiloxane), or any combination thereof. The fourth sacrificial anode material layer 450 can be deposited using an organic thermal evaporator. In one or more examples, the fourth sacrificial anode material layer 450 is formed in the fourth compartment 134 of the third sub-chamber 130 using an organic thermal evaporation source 138 configured to deposit the fourth sacrificial anode material layer 450. In one or more examples, the fourth sacrificial anode material layer 450 is a poly(dimethylsiloxane) layer. In other examples, the fourth sacrificial anode material layer 450 is a hydrophilic polymer layer such as a coating containing polyethylene glycol (PEG) with a water contact angle less than 40 degrees.

At operation 360, at least one of the previously deposited sacrificial anode material layers is exposed to a physical densification process. The sacrificial anode material layers can be exposed to electron irradiation or induction heating during the physical densification process. The electron irradiation or induction heating physically densifies the previously deposited sacrificial anode material layers. The densification process can be performed using an electron gun. In one or more examples, the densification process is performed using the electron gun 214. In other examples, the web or continuous sheet of flexible material 150 is heated by radio frequency (RF) magnetic fields induced by Helmholtz-like coils that generate rapidly varying eddy currents.

Optionally, at operation 370, the pre-lithiated anode structure 400 can be examined to validate the thickness determination performed during operation 305 and determine the quality of the deposited material. The pre-lithiated anode structure 400 can be examined using beta ray instrumentation or other metrology. The results can be used to update future recipes in a feedback process.

At operation 380, the pre-lithiated anode structure 400 is removed from the flexible substrate coating system 100. The pre-lithiated anode structure 400 can be used to assemble a pre-lithiated type lithium-ion battery having reduced first cycle loss.

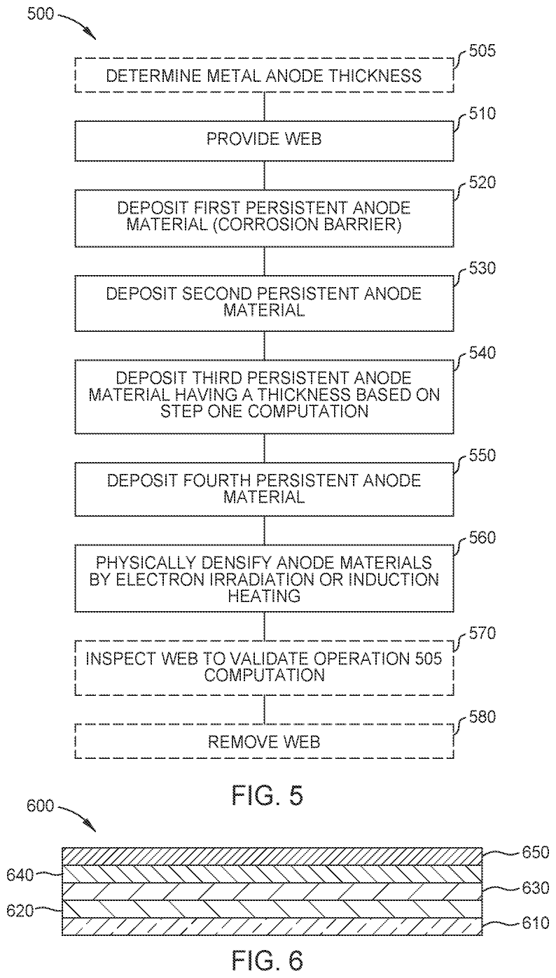

FIG. 5 illustrates a process flow chart summarizing one implementation of a processing sequence 500 of forming a metal anode structure according to one or more implementations of the present disclosure. FIG. 6 illustrates a schematic cross-sectional view of an anode structure 600 formed according to the processing sequence 500 of FIG. 5. The processing sequence 500 can be used to form a single-sided metal anode structure or a dual-sided metal anode structure. The processing sequence 500 can be performed using, for example, a coating system, such as the flexible substrate coating system 100 depicted in FIG. 1 including the deposition module 200 of FIG. 2.

Optionally, at operation 505, the thickness of the metal anode layer to be deposited is determined. The thickness of the metal anode layer can be based on factors such as lithium loss during cell assembly, for example Li₂O formation; ageing, for example, silicon oxide formation; and cycling, for example, SEI formation.

At operation 510, a web or the continuous sheet of flexible material 150 is provided. In some implementations, the continuous sheet of flexible material 150 includes a current collector. In another implementation, the web or continuous sheet of flexible material 150 includes a polymer material on which a current collector is subsequently formed. The polymer material can be a resin film selected from a polypropylene film, a polyethylene terephthalate (PET) film, a polyphenylene sulfite (PPS) film, and a polyimide (PI) film. The continuous sheet of flexible material 150 can include a base material layer 610. The base material layer 610 can include a substrate. The substrate can be a current collector as described herein. Examples of metals that the current collectors can be comprised of include aluminum (Al), copper (Cu), zinc (Zn), nickel (Ni), cobalt (Co), tin (Sn), silicon (Si), manganese (Mn), magnesium (Mg), alloys thereof, or combinations thereof. The substrate can be a flexible substrate or web, such as the continuous sheet of flexible material 150, which can be used in a roll-to-roll coating system. In one aspect, the substrate is a negative current collector, such as a copper current collector.

At operation 520, a first persistent anode material, for example, first persistent anode material layer 620 is deposited on the base material layer 610. In some implementations, the first persistent anode material layer 620 functions as a corrosion barrier, which minimizes electrochemical resistance between the current collector and the subsequently deposited lithium metal anode film. The first persistent anode material layer 620 comprises, consists essentially of, or consists of aluminum, nickel, copper, alumina (Al₂O₃), boron nitride (BN), carbon, silicon oxide, or a combination thereof. Not to be bound by theory, but it is believed that the first persistent anode material layer 620 minimizes corrosion and reduces bagginess of the underlying continuous metal sheet of flexible material 150. The first persistent anode material layer 620 can be deposited using a sputtering source. In one or more examples, the first persistent anode material layer 620 is formed in the first sub-chamber 110 using a deposition source 113, which is a sputtering source configured to deposit the first persistent anode material layer 620.

At operation 530, a second persistent anode material, for example, second persistent anode material layer 630 is deposited on the first persistent anode material layer 620. The second persistent anode material layer 630 functions as a corrosion barrier, which minimizes electrochemical resistance between the current collector and the subsequently deposited metal anode film. The second persistent anode material layer 630 comprises, consists essentially of, or consists of a binary lithium compound, a ternary lithium compound, or a combination thereof. The second persistent anode material layer 630 can be deposited using an electron beam evaporation source. In one or more examples, the second persistent anode material layer 630 is formed in the first compartment 122 of the second sub-chamber 120 using the first evaporation source, for example, the electron beam evaporation source 210, configured to deposit the second persistent anode material layer 630. In one or more examples, the second persistent anode material layer 630 is a lithium fluoride layer.

At operation 540, a third persistent anode material, for example, third persistent anode material layer 640 is deposited on the second persistent anode material layer 630. The third persistent anode material layer 640 functions as a lithium metal anode layer. The third persistent anode material layer 640 comprises, consists essentially of, or consists of lithium metal. The third persistent anode material layer 640 can be deposited using a thermal evaporation source. In one or more examples, the third persistent anode material layer 640 is formed in the second compartment 124 of the second sub-chamber 120 using the deposition source 128, which is a thermal evaporation source configured to deposit the third persistent anode material layer 640. In one or more examples, third persistent anode material layer 640 is a lithium metal layer.

At operation 550, a fourth persistent anode material, for example, fourth persistent anode material layer 650 is deposited on the third persistent anode material layer 640. The fourth persistent anode material layer 650 functions as an oxidation barrier, which minimizes electrochemical resistance between the lithium metal layer and electrolyte in the formed cell. The fourth persistent anode material layer 650 comprises, consists essentially of, or consists of a binary lithium compound, a ternary lithium compound, a sulfide compound, an oxide combination, a polymer, or a combination thereof. The fourth persistent anode material layer 650 can be deposited using an electron beam evaporation source. In one or more examples, the fourth persistent anode material layer 650 is formed in the third compartment 132 of the third sub-chamber 130 using the deposition source 136, which can be an electron beam evaporation source or a thermal organic evaporation source configured to deposit the third sacrificial anode material layer 440. In one or more examples, the fourth persistent anode material layer 650 is a lithium fluoride layer.

At operation 560, at least one of the previously deposited persistent anode material layers is exposed to a physical densification process. The persistent anode material layers can be exposed to electron irradiation or induction heating during the physical densification process. The electron irradiation or induction heating physically densifies the previously deposited sacrificial anode material layers. The densification process can be performed using an electron gun. In one or more examples, the densification process is performed using the electron gun 214. In other examples, the web or continuous sheet of flexible material 150 is heated by radio frequency (RF) magnetic fields induced by Helmholtz-like coils that generate rapidly varying eddy currents.

Optionally, at operation 570, the anode structure 600 can be examined to validate the thickness determination performed during operation 505 and determine the quality of the deposited material. The anode structure 600 can be examined using beta ray instrumentation or other metrology. The results can be used to update future recipes in a feedback process.

At operation 580, the anode structure 600 is removed from the flexible substrate coating system 100. The anode structure 600 can be used to assemble a lithium anode type lithium-ion battery having reduced first cycle loss.

Implementations can include one or more of the following potential advantages. State of the art EV and CE anode protection involve the ability to tune pre-metalation thickness. Carbonate coatings consume lithium, which decreases coulombic efficiency, and are difficult to activate given the slow adsorption rate can cause significant variation in carbonate coating uniformity in the machine and transverse directions. One or more implementations of the present disclosure include a general coating architecture that can rapidly scale protection layer material systems that are compatible with solid electrolytes. For pre-lithiation, one advantage of electrochemically active protection layers is the ability to simplify downstream workflows. In addition, extended handling time is available if the metallic lithium is sandwiched between two barriers. Further, protection layers can be tuned via electron beam irradiation in order to add functionality such as improved electrolyte wetting. For lithium metal anodes, one advantage of electrochemically active protection layers is the ability to address dendrites. For both pre-lithiation and lithium metal anodes, the electrochemically active coatings are colorful and therefore can benefit from advanced metrology-based process control.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

Embodiments of the present disclosure further relate to any one or more of the following examples 1-44:

1. A flexible substrate coating system, comprising: an unwinding module housing a feed reel capable of providing a continuous sheet of flexible material; a winding module housing a take-up reel capable of storing the continuous sheet of flexible material; a processing module arranged downstream from the unwinding module, the processing module, comprising: a plurality of sub-chambers arranged in sequence, each configured to perform one or more processing operations to the continuous sheet of flexible material; and a coating drum capable of guiding the continuous sheet of flexible material past the plurality of sub-chambers along a travel direction, wherein the sub-chambers are radially disposed about the coating drum and at least one of the sub-chambers comprises: a deposition module, comprising: a pair of electron beam sources positioned side-by-side along a transverse direction, wherein the transverse direction is perpendicular to the travel direction.

2. The coating system according to example 1, wherein the deposition module is defined by a sub-chamber body with an edge shield positioned over the sub-chamber body.

3. The coating system according to example 1 or 2, wherein the edge shield has one or more apertures defining a pattern of evaporated material that is deposited on the continuous sheet of flexible material.

4. The coating system according to any one of examples 1-3, wherein the edge shield has at least two apertures, with a first aperture defining a first strip of deposited material and a second aperture defining a second strip of deposited material.

5. The coating system according to any one of examples 1-4, wherein each electron beam source comprises at least one crucible capable of holding an evaporable material and an electron gun.

6. The coating system according to any one of examples 1-5, wherein the electron gun is operable for emitting an electron beam toward the evaporable material positioned in the crucible.

7. The coating system according to any one of examples 1-6, wherein each electron beam source further comprises e-gun steering capable of directing the electron beam of the electron gun from the evaporable material toward the continuous sheet of flexible material for electron irradiation of the deposited material on the continuous sheet of flexible material.

8. The coating system according to any one of examples 1-7, wherein the deposition module further comprises an optical detector positioned to monitor a plume of evaporated material emitted from the electron beam source.

9. The coating system according to any one of examples 1-8, wherein the optical detector is configured to perform optical emission spectroscopy to measure the intensity of one or more wavelengths of light associated with the plume of evaporated material.

10. The coating system according to any one of examples 1-9, wherein the pair of electron beam sources are configured to deposit a lithium fluoride film on the continuous sheet of flexible material.

11. The coating system according to any one of examples 1-10, wherein the plurality of sub-chambers further comprises: a first sub-chamber comprising a sputtering source, wherein the first sub-chamber is positioned upstream from the sub-chamber comprising the deposition module.

12. The coating system according to any one of examples 1-11, wherein the sputtering source is configured to deposit at least one of aluminum, nickel, copper, alumina, boron nitride, carbon, silicon oxide, or combinations thereof.

13. The coating system according to any one of examples 1-12, wherein the sub-chamber comprising the deposition module further comprises a second sub-chamber comprising a thermal evaporation source.

14. The coating system according to any one of examples 1-13, wherein the thermal evaporation source is configured to deposit lithium metal.

15. The coating system according to any one of examples 1-14, wherein the plurality of sub-chambers further comprises a third sub-chamber comprising a second deposition module similar to the deposition module and positioned downstream from the sub-chamber comprising the deposition module.

16. The coating system according to any one of examples 1-15, wherein the second deposition module is configured to deposit lithium fluoride.

17. The coating system according to any one of examples 1-16, wherein the third sub-chamber further comprises a fourth sub-chamber comprising an organic thermal evaporation source.

18. The coating system according to any one of examples 1-17, further comprising a chemical vapor deposition (CVD) module positioned between the processing module and the winding module.

19. The coating system according to any one of examples 1-18, wherein the CVD module comprises a multi-zone gas distribution assembly.

20. The coating system according to any one of examples 1-19, wherein the multi-zone gas distribution assembly is fluidly coupled with a first gas source.

21. The coating system according to any one of examples 1-20, wherein the first gas source is configured to supply at least one of titanium tetrachloride, boron phosphate, TiCl₄(HSR)₂, where R=C₆H₁₁ or C₅H₉, or combinations thereof.

22. The coating system according to any one of examples 1-21, wherein the multi-zone gas distribution assembly is fluidly coupled with a second gas source.

23. The coating system according to any one of examples 1-22, wherein the second gas source is configured to supply at least one of hydrogen sulfide, carbon dioxide, perfluorodecyltrichlorosilane (FDTS), and polyethylene glycol (PEG).

24. A method of forming a pre-lithiated anode structure, comprising: depositing a first sacrificial anode layer on a prefabricated electrode structure, wherein the prefabricated electrode structure comprises a continuous sheet of flexible material coated with anode material; depositing a second sacrificial anode layer on the first sacrificial anode layer; depositing a third sacrificial anode layer on the second sacrificial anode layer; and densifying at least one of the first sacrificial anode layer, the second sacrificial anode layer, and the third sacrificial anode layer by exposing the sacrificial anode layers to electron beams from a pair of electron beam sources.

25. The method according to example 24, wherein the anode material is selected from graphite anode material, silicon anode material, or silicon-graphite anode material.

26. The method according example 24 or 25, wherein the first sacrificial anode layer functions as a corrosion barrier, which minimizes electrochemical resistance between the anode material and/or the substrate and the second sacrificial anode layer.

27. The method according to any one of examples 24-26, wherein the first sacrificial anode layer comprises a binary lithium compound, a ternary lithium compound, or a combination thereof.

28. The method according to any one of examples 24-27, wherein the first sacrificial anode layer is deposited using an electron beam evaporation source.

29. The method according to any one of examples 24-28, wherein the first sacrificial anode layer is a lithium fluoride layer.

30. The method according to any one of examples 24-29, wherein the second sacrificial anode material layer functions as a pre-lithiation layer, which provides lithium to pre-lithiate the prefabricated electrode structure.

31. The method according to any one of examples 24-30, wherein the second sacrificial anode layer is a lithium metal layer.

32. The method according to any one of examples 24-31, wherein the third sacrificial anode layer functions as an oxidation barrier, which minimizes electrochemical resistance between the lithium metal layer and subsequently deposited electrolyte.

33. The method according to any one of examples 24-32, wherein the third sacrificial anode layer comprises a binary lithium compound, a ternary lithium compound, a sulfide compound, an oxide combination or a combination thereof.

34. The method according to any one of examples 24-33, wherein the third sacrificial anode layer is a lithium fluoride layer.

35. The method according to any one of examples 24-34, further comprising depositing a fourth sacrificial layer on the third sacrificial anode layer, wherein the fourth sacrificial layer functions as a wetting layer.

36. The method according to any one of examples 24-35, wherein the fourth sacrificial anode layer comprises a polymer material selected from polymethylmethacrylate, polyethylene oxide, polyacrylonitrile, polyvinylidene fluoride, poly(vinylidene fluoride)-co-hexafluoropropylene, polypropylene, nylon, polyamides, polytetrafluoroethylene, polychlorotrifluoroethylene, polyterephthalate, silicone, silicone rubber, polyurethane, cellulose acetate, polystyrene, poly(dimethylsiloxane), or combinations thereof.

37. A method of forming an anode structure, comprising: depositing a first persistent anode layer on a continuous sheet of flexible material; depositing a second persistent anode layer on the first persistent lithium anode layer; depositing a third persistent anode layer on the second persistent anode layer, wherein the third persistent anode layer is a lithium metal layer; and densifying at least one of the first persistent lithium anode layer, the second persistent anode layer, and the third persistent anode layer by exposing the persistent anode layers to electron beams from a pair of electron beam sources.

38. The method according to example 37, wherein the first persistent anode layer functions as a corrosion barrier, which minimizes electrochemical resistance between the continuous sheet of flexible material and the second persistent anode layer.

39. The method according to example 37 or 38, wherein the first persistent anode layer comprises first persistent anode material layer comprises aluminum, nickel, copper, alumina (Al₂O₃), boron nitride (BN), carbon, silicon oxide, or a combination thereof.

40. The method according to any one of examples 37-39, wherein the first persistent anode layer is deposited using a sputtering source.

41. The method according to any one of examples 37-40, wherein the second persistent anode layer functions as a corrosion barrier, which minimizes electrochemical resistance between the continuous sheet of flexible material and the third persistent anode layer.

42. The method according to any one of examples 37-41, wherein the second persistent anode layer comprises a binary lithium compound, a ternary lithium compound, or a combination thereof.

43. The method according to any one of examples 37-42, wherein the second persistent anode layer is deposited using an electron beam evaporation source.

44. The method according to any one of examples 37-43, wherein the second persistent anode layer is a lithium fluoride layer.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” or “having” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. When introducing elements of the present disclosure or exemplary aspects or implementation(s) thereof, the articles “a,” “an,” “the” and “said” are intended to mean that there are one or more of the elements.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A flexible substrate coating system, comprising:
an unwinding module housing a feed reel capable of providing a continuous sheet of flexible material;
a winding module housing a take-up reel capable of storing the continuous sheet of flexible material; and
a processing module arranged downstream from the unwinding module, the processing module, comprising:
a plurality of sub-chambers arranged in sequence, each configured to perform one or more processing operations to the continuous sheet of flexible material; and
a coating drum capable of guiding the continuous sheet of flexible material past the plurality of sub-chambers along a travel direction, wherein the sub-chambers are radially disposed about the coating drum and at least one of the sub-chambers comprises:
a deposition module, comprising:
a pair of electron beam sources positioned side-by-side along a transverse direction, wherein the transverse direction is perpendicular to the travel direction.

2. The coating system of claim 1, wherein the deposition module is defined by a sub-chamber body with an edge shield positioned over the sub-chamber body, and wherein the edge shield has one or more apertures defining a pattern of evaporated material that is deposited on the continuous sheet of flexible material.

3. The coating system of claim 2, wherein the edge shield has at least two apertures, with a first aperture defining a first strip of deposited material and a second aperture defining a second strip of deposited material.

4. The coating system of claim 1, wherein the deposition module further comprises an optical detector positioned to monitor a plume of evaporated material emitted from at least one of the pair of electron beam sources, and wherein the optical detector is configured to perform optical emission spectroscopy to measure the intensity of one or more wavelengths of light associated with the plume of evaporated material.

5. The coating system of claim 1, wherein each electron beam source comprises at least one crucible capable of holding an evaporable material and an electron gun, wherein the electron gun is operable for emitting an electron beam toward the evaporable material positioned in the crucible, and wherein each electron beam source further comprises e-gun steering capable of directing the electron beam of the electron gun from the evaporable material toward the continuous sheet of flexible material for electron irradiation of the deposited material on the continuous sheet of flexible material.

6. The coating system of claim 1, wherein the pair of electron beam sources is configured to deposit a lithium fluoride film on the continuous sheet of flexible material.

7. The coating system of claim 1, wherein the plurality of sub-chambers further comprises a first sub-chamber comprising a sputtering source, wherein the first sub-chamber is positioned upstream from the sub-chamber comprising the deposition module, and wherein the sputtering source is configured to deposit at least one material selected from aluminum, nickel, copper, alumina, boron nitride, carbon, silicon oxide, or combinations thereof.

8. The coating system of claim 1, wherein the sub-chamber comprising the deposition module further comprises a second sub-chamber comprising a thermal evaporation source, and wherein the thermal evaporation source is configured to deposit lithium metal.

9. The coating system of claim 1, wherein the plurality of sub-chambers further comprises a third sub-chamber comprising a second deposition module similar to the deposition module and positioned downstream from the sub-chamber comprising the deposition module, and wherein the second deposition module is configured to deposit lithium fluoride.

10. The coating system of claim 1, further comprising a chemical vapor deposition (CVD) module positioned between the processing module and the winding module, wherein the CVD module comprises a multi-zone gas distribution assembly.

11. The coating system of claim 10, wherein the multi-zone gas distribution assembly is fluidly coupled with a first gas source, and wherein the first gas source is configured to supply at least one of titanium tetrachloride, boron phosphate, TiCl₄(HSR)₂, where R is C₆H₁₁ or C₅H₉, or combinations thereof.

12. The coating system of claim 10, wherein the multi-zone gas distribution assembly is fluidly coupled with a second gas source, and wherein the second gas source is configured to supply at least one of hydrogen sulfide, carbon dioxide, perfluorodecyltrichlorosilane (FDTS), and polyethylene glycol (PEG).

13. A method of forming a pre-lithiated anode structure, comprising:
depositing a first sacrificial anode layer on a prefabricated electrode structure, wherein the prefabricated electrode structure comprises a continuous sheet of flexible material coated with anode material;
depositing a second sacrificial anode layer on the first sacrificial anode layer;
depositing a third sacrificial anode layer on the second sacrificial anode layer; and
densifying at least one of the first sacrificial anode layer, the second sacrificial anode layer, and the third sacrificial anode layer by exposing the sacrificial anode layers to electron beams from a pair of electron beam sources.

14. The method of claim 13, wherein the first sacrificial anode layer functions as a corrosion barrier, which minimizes electrochemical resistance between the anode material and/or the substrate and the second sacrificial anode layer, and wherein the first sacrificial anode layer comprises a binary lithium compound, a ternary lithium compound, or a combination thereof.

15. The method of claim 13, wherein the second sacrificial anode material layer functions as a pre-lithiation layer, which provides lithium to pre-lithiate the prefabricated electrode structure, wherein the second sacrificial anode layer is a lithium metal layer, and wherein the third sacrificial anode layer functions as an oxidation barrier, which minimizes electrochemical resistance between the lithium metal layer and subsequently deposited electrolyte.

16. The method of claim 13, wherein the third sacrificial anode layer comprises a binary lithium compound, a ternary lithium compound, a sulfide compound, an oxide combination or a combination thereof.

17. The method of claim 13, further comprising depositing a fourth sacrificial layer on the third sacrificial anode layer, wherein the fourth sacrificial layer functions as a wetting layer, wherein the fourth sacrificial anode layer comprises a polymer material selected from polymethylmethacrylate, polyethylene oxide, polyacrylonitrile, polyvinylidene fluoride, poly(vinylidene fluoride)-co-hexafluoropropylene, polypropylene, nylon, polyamides, polytetrafluoroethylene, polychlorotrifluoroethylene, polyterephthalate, silicone, silicone rubber, polyurethane, cellulose acetate, polystyrene, poly(dimethylsiloxane), or combinations thereof.

18. A method of forming an anode structure, comprising:
depositing a first persistent anode layer on a continuous sheet of flexible material;
depositing a second persistent anode layer on the first persistent lithium anode layer;
depositing a third persistent anode layer on the second persistent anode layer, wherein the third persistent anode layer is a lithium metal layer; and
densifying at least one of the first persistent lithium anode layer, the second persistent anode layer, and the third persistent anode layer by exposing the persistent anode layers to electron beams from a pair of electron beam sources.

19. The method of claim 18, wherein the first persistent anode layer functions as a corrosion barrier, which minimizes electrochemical resistance between the continuous sheet of flexible material and the second persistent anode layer, wherein the first persistent anode layer comprises first persistent anode material layer comprises aluminum, nickel, copper, alumina (Al₂O₃), boron nitride (BN), carbon, silicon oxide, or a combination thereof, and wherein the first persistent anode layer is deposited using a sputtering source.

20. The method of claim 18, wherein the second persistent anode layer functions as a corrosion barrier, which minimizes electrochemical resistance between the continuous sheet of flexible material and the third persistent anode layer, wherein the second persistent anode layer comprises a binary lithium compound, a ternary lithium compound, or a combination thereof, and wherein the second persistent anode layer is deposited using an electron beam evaporation source.
